(19) United States
(12) Patent Application Publication
(10) Pub. No.: US 2024/0304506 A1
(43) Pub. Date: Sep. 12, 2024

(54) INTEGRATED ANTIOXIDANT AND SEALANT SOLUTION TO ADDRESS TEMPERATURE HUMIDITY RELIABILITY ISSUE OF LIQUID METAL INTERCONNECT

(71) Applicant: Intel Corporation, Santa Clara, CA (US)

(72) Inventors: Sangeon LEE, Chandler, AZ (US); Tingting GAO, Chandler, AZ (US); Xiao LU, Chandler, AZ (US); Matthew MAGNAVITA, Chandler, AZ (US); Khalid ABDELAZIZ, Chandler, AZ (US)

(21) Appl. No.: 18/117,818

(22) Filed: Mar. 6, 2023

(51) Int. Cl. H01L 23/29; H01L 23/31; H01L 23/498

(52) U.S. Cl. CPC H01L 23/296; H01L 23/3107; H01L 23/49811; H01L 23/49894

(57) ABSTRACT

Embodiments disclosed herein include socket interconnects with liquid metal. In an embodiment, a board comprises a substrate. A pad may be provided over the substrate. In an embodiment, a confinement layer is over the substrate, where the confinement layer defines a cavity over the pad. In an embodiment, a liquid metal is on the pad within the cavity. In an embodiment, a protective layer is provided over the liquid metal.

### TECHNICAL FIELD

Embodiments of the present disclosure relate to electronic systems, and more particularly to electronic systems with liquid metal interconnects that further include an antioxidant solution to prevent oxidation of the liquid metal in elevated temperatures with high humidity.

### BACKGROUND

Liquid metals are an attractive option for interconnect architectures between a package substrate and a board. For example, liquid metals are particularly beneficial for second level interconnect (SLI) applications that include socket based architectures. This is because the pin can be surrounded by the liquid metal to provide improved connections, and the pins can be removed easily. This enables simple upgrades or replacement of defective systems. While SLI applications have been thoroughly investigated, liquid metal solutions may also be used for first level interconnect (FLI) applications between a die and a package substrate.

One potentially useful material class for liquid metal applications is a gallium based liquid metal. Gallium based systems have unique properties of a low melting point (e.g., below or near room temperature), low toxicity, low viscosity, and excellent electrical and thermal conductivity. While the potential benefits of such material systems are evident, one failure mechanism makes gallium bases solutions susceptible to failure. Particularly, in high temperature (e.g., 85 degrees Celsius and above) and high humidity environments, the gallium liquid metal forms a gallium oxide monohydroxide crystal structure (e.g., GaOOH). The GaOOH is solid at room temperature. Also, the GaOOH material is not electrically conductive. As such, reliability concerns are currently a limiting factor for gallium based liquid metal solutions.

### BRIEF DESCRIPTION OF THE DRAWINGS

FIG. 1 is a cross-sectional illustration of a board with a cavity that is filled with a liquid metal, in accordance with an embodiment.

FIG. 2 is an illustration of a liquid metal that is oxidized during exposure to heat and humidity, in accordance with an embodiment.

FIG. 3 is a cross-sectional illustration of a board with a cavity that is filled with liquid metal that has been oxidized so that it extrudes out the top of the cavity, in accordance with an embodiment.

FIG. 4 is a cross-sectional illustration of a board with a cavity that is filled with a liquid metal that includes oxidation prevention solutions, in accordance with an embodiment.

FIG. 5A is a scanning electron microscopy (SEM) image of a liquid metal that is oxidized to form metal oxide monohydroxide crystals, in accordance with an embodiment.

FIG. 5B is a SEM image of a liquid metal that maintains the liquid properties upon exposure to a high temperature and a high humidity, in accordance with an embodiment.

FIG. 5C is a schematic illustration of a liquid metal that has been oxidized and is no longer electrically conductive, in accordance with an embodiment.

FIG. 5D is a schematic illustration of a liquid metal with a thin outer oxide layer that does not significantly impact electrical conductivity, in accordance with an embodiment.

FIG. 6 is an illustration of a liquid metal that is coated by a protective layer, such as an antioxidant, in accordance with an embodiment.

FIG. 7 is a cross-sectional illustration of a board with a cavity that is filled with a liquid metal and a protective layer, in accordance with an embodiment.

FIG. 8A is an illustration of a nozzle that is dispensing a liquid metal into a plurality of cavities on a board, in accordance with an embodiment.

FIG. 8B is an illustration of a nozzle that is dispensing a protective layer into the plurality of cavities over the liquid metal, in accordance with an embodiment.

FIG. 9 is a process flow diagram of a process used to form a board with liquid metal that is protected from oxidation by a protection layer, in accordance with an embodiment.

FIG. 10A is an energy dispersive X-ray (EDX) plot of a liquid metal without a protective layer, in accordance with an embodiment.

FIG. 10B is an EDX plot of a liquid metal with a protective layer, in accordance with an embodiment.

FIG. 11 is a cross-sectional illustration of an electronic system that includes a second level interconnect (SLI) between the board and the package that uses a liquid metal that is protected by an antioxidant, in accordance with an embodiment.

FIG. 12 is a schematic of a computing device built in accordance with an embodiment.

### EMBODIMENTS OF THE PRESENT DISCLOSURE

Described herein are electronic systems, and more particularly, electronic systems with liquid metal interconnects that further include an antioxidant solution to prevent oxidation of the liquid metal in elevated temperatures with high humidity, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

To provide context, socketing architectures with liquid metal materials have been an area of interest for forming interconnect architectures. For example, a socketing structure with a liquid metal in a cavity that is penetrated by a pin has been investigated for advanced packaging applications. In some instances, the cavity may be on the board for a second level interconnect (SLI). Though, first level interconnect (FLI) architectures may also use liquid metal systems as well. As used herein, liquid metal materials are material compositions that comprise a metal, and the material composition exhibits a liquid phase at low temperatures, e.g., at or near room temperature. In some embodiments, a liquid metal material may have a liquid phase down to temperatures around 0 degrees Celsius.

Gallium based liquid metal is one material class that has been proposed for socket based architectures. As noted above, gallium based materials have a low melting point (e.g., below or near room temperature), low toxicity, low viscosity, and excellent electrical and thermal conductivity. As such, a pin may be inserted into the gallium based liquid metal in order to provide good electrical coupling to an underlying pad. While gallium based materials have promising properties, there is at least one drawback for existing gallium based systems. Particularly, at high temperatures (e.g., at or around 85 degrees Celsius) and/or at a high humidity (e.g., at or around 85%), the liquid metal oxidizes and forms gallium oxide monohydroxide crystallites (e.g., GaOOH). The transformation renders the material solid and porous. Additionally, the electrical conductivity is significantly reduced.

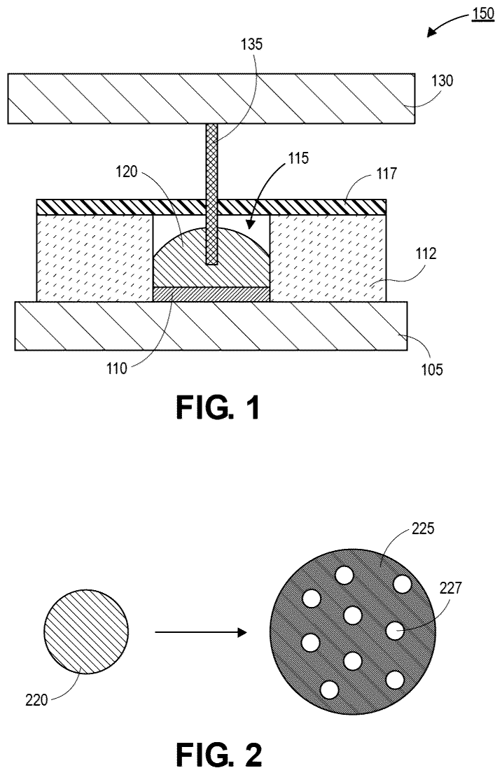

Referring now to FIG. 1, a cross-sectional illustration of a system 150 is shown, in accordance with an embodiment. In an embodiment, the system 150 may include a board 105, such as a printed circuit board (PCB). In an embodiment, a pad 110 on the board 105 is electrically coupled to a package substrate 130 by a pin 135. The pin 135 may be electrically coupled to the pad 110 through a liquid metal 120. The liquid metal 120 may be confined by a confinement layer 112 that defines a cavity 115. The liquid metal 120 may be held within the cavity 115. The confinement layer 112 may include an oxide, a polymer, or any other electrically insulating material. In an embodiment, the liquid metal 120 partially fills the cavity 115. Though, in some embodiments, the cavity 115 may be substantially filled by the liquid metal 120. The top of the cavity 115 may be sealed by a capping layer 117. The capping layer 117 may be an electrically insulating material that can seal the cavity 115 to minimize the amount of air or moisture that enter the cavity 115. The capping layer 117 may be pierced by the pin 135.

In an embodiment, the liquid metal 120 may comprise a gallium based liquid metal. The gallium may be alloyed with other elements such as, for example, tin, zinc, indium, and other metallic elements. In an embodiment, the liquid metal 120 may comprise approximately 80 atomic percent gallium or more, approximately 90 atomic percent gallium or more, or approximately 99 atomic percent gallium or more. Despite the presence of the capping layer 117, moisture and/or oxygen may penetrate into the cavity 115 and cause oxidation of the liquid metal 120 that results in the formation of GaOOH crystals, which negatively impacts performance of the system 150.

Referring now to FIG. 2, a schematic of the transformation of a liquid metal 220 into an oxidized solid 225 is shown, in accordance with an embodiment. In an embodiment, the liquid metal 220 in a native state has the properties of a liquid. For example, the liquid metal 220 may have a viscosity that is similar to the viscosity of liquid water. As such, the liquid metal 220 easily conforms to the shape of a conductive pin in a socket like architecture (e.g., similar to what is shown in FIG. 1). The liquid metal 220 provides the necessary electrical connection between the pin and an underlying pad.

However, when exposed to oxygen and water, the liquid metal 220 may oxidize to form an oxidized solid 225. For example, the transformation may occur when exposed to a relatively high temperature and/or a relatively high humidity. A relatively high temperature may include temperatures that are approximately 50 degrees Celsius or higher or approximately 85 degrees Celsius or higher. A relatively high humidity may include a humidity of approximately 50% or higher or approximately 85% or higher. The presence of both high temperature and high heat may increase the rate of oxidation. As used herein, “approximately” may refer to a range within ten percent of the stated value. For example, approximately 50% may refer to a range from 45% to 55%.

In an embodiment, the oxidized solid 225 may comprise GaOOH crystallites and/or gallium oxide (e.g., Ga₂O₃). The oxidized solid 225 may also include a porous structure. For example, pores 227 may be provided throughout the oxidized solid 225. Additionally, the oxidation process may result in an increase in the volume compared to the liquid metal 220 state. As such, when confined (e.g., in the case of a cavity), the oxidized solid 225 may extruded out of the cavity, as will be described in greater detail below.

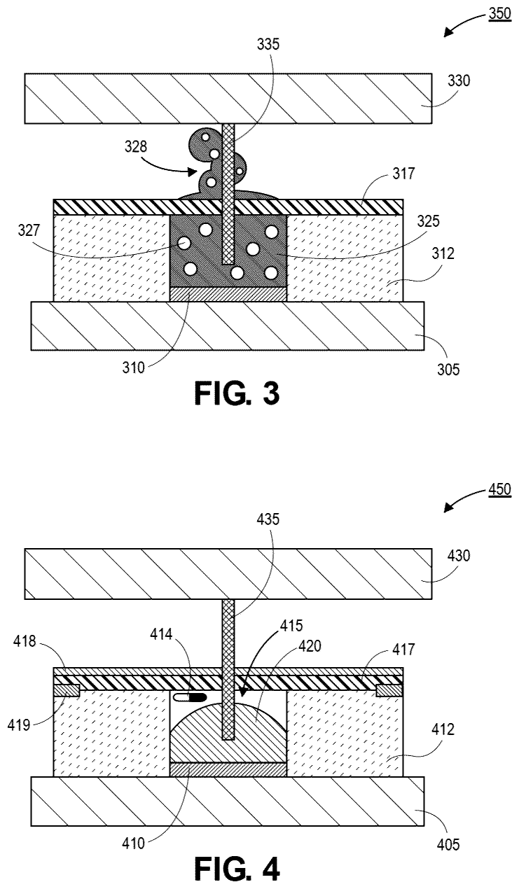

Referring now to FIG. 3, a cross-sectional illustration of system 350 is shown, in accordance with an embodiment. As shown, the system 350 may include a board 305. The board 305 may be coupled to a package substrate 330 through a pin 335. In an embodiment, a confinement layer 312 may form a cavity that is provided over the pad 310. The cavity may be filled by an oxidized metal 325. The oxidized metal 325 may be the oxidized form of a liquid metal, such as a gallium based liquid metal. In addition to GaOOH crystals and Ga₂O₃ oxide, pores 327 may be included. Prior to oxidation, the system 350 may be similar to the embodiment shown in FIG. 1. After oxidation, the oxidized metal 325 may have a volume that exceeds the volume of the cavity. Accordingly, portions 328 may be extruded out above the capping layer 317. In some instances, the oozing process may be referred to as “snaking” since the portion 328 may have a generally cylindrical shape (like that of a snake) that grows up from the cavity. As noted above, the oxidized metal 325 may be converted into a solid. Since the oxidized metal 325 is solid, it may be difficult to remove the pin 335 from the cavity without damaging the system 350. Additionally, the oxidized metal 325 is no longer electrically conductive, and an electrical connection between the pin 335 and the pad 310 is no longer provided.

Referring now to FIG. 4, a cross-sectional illustration of a system 450 that includes some proposed solutions to mitigate oxidation is shown, in accordance with an embodiment. The system 450 may comprise a board 405 with a pad 410. A confinement layer 412 may define a cavity 415. A liquid metal 420 may be confined in the cavity 415. A pin 435 that is coupled to a package substrate 430 is inserted through a capping layer 417 to make contact with the liquid metal 420. As such, the package substrate 430 is electrically coupled to the pad 410.

The system 450 in FIG. 4 may have oxidation mitigation features. However, each of the features disclosed in FIG. 4 have drawbacks that limit their effectiveness. A first option is to add an insulation layer or a hydrophobic coating 418 to the capping layer 417. Hydrophobic coatings usually last for a limited duration of time before the coating 418 needs to be reapplied. Hydrophobic coatings are also very sensitive to heat. That is, the coating 418 may degrade rapidly at high temperatures. Hydrophobic coatings are also vulnerable to socket pin penetration and other mechanical damage.

In another instances, a socket edge sealant 419 may be applied between the capping layer 417 and the confinement layer 412. However, sealants 419 are not durable, and they need to be replaced on a regular basis, especially under humid conditions. Typically, the failure mechanism of a sealant 419 may be an adhesive failure, which allows for water to seep through small cracks. Socket edge sealants 419 will also result in reoccurring costs to the end user for every time re-socketing is needed.

In yet another instance, a desiccant 414 may be placed in the cavity 415. However, desiccants 414 need to be replaced periodically for open-cycle systems. A desiccant 414 degrades very quickly in a humid and hot environment. Additionally, the cavity 415 may not be large enough to provide sufficient space for the desiccant 414.

A complete reformulation of the liquid metal 420 may also be used to mitigate oxidation. However, reformulations are complex and challenging efforts. Further, an improved liquid metal 420 formulation can still be paired with embodiments disclosed herein in order to further improve performance.

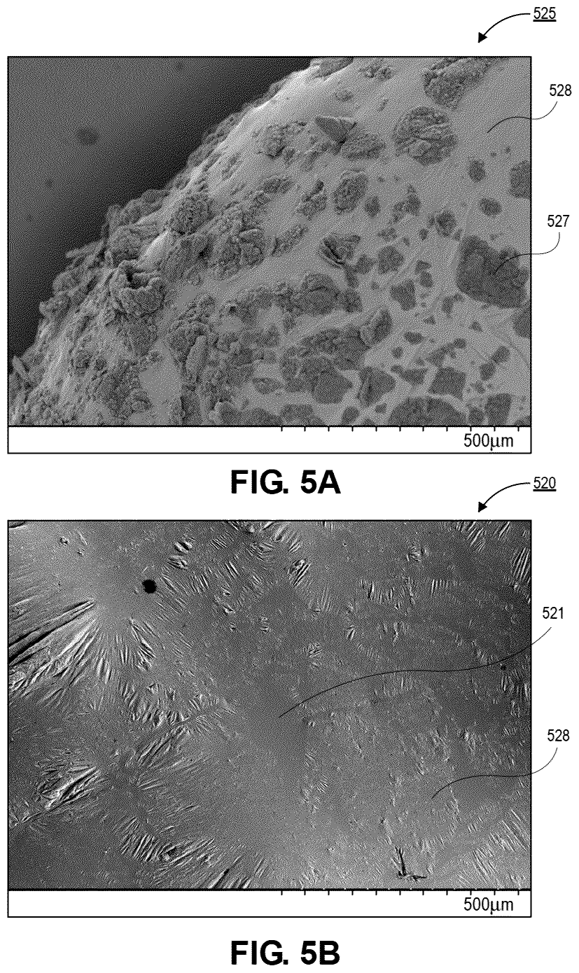

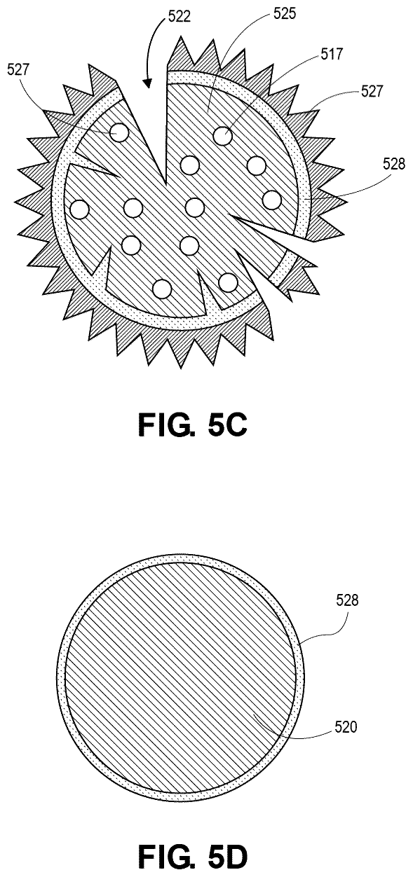

Referring now to FIG. 5A, an image of an oxidized liquid metal 525 is shown, in accordance with an embodiment. The image shown in FIG. 5A may be a SEM image that is used to inspect a surface of the oxidized liquid metal 525. As shown, the surface may be covered by metal oxide monohydroxide crystal structures 527. For example, in the case of a gallium based liquid metal, the surface may be covered by gallium oxide monohydroxide crystals (GaOOH) 527. The GaOOH 527 may be an oxide that is porous and protrudes up from a surface of the liquid metal. With longer exposure to heat and/or humidity, the percentage of the surface that converts to GaOOH 527 increases. The other portion of the surface of the oxidized liquid metal 525 may be covered by a metal oxide 528, such as gallium oxide (e.g., Ga₂O₃). The metal oxide 528 may have a thickness that is approximately 1 μm or more. In combination, the presence of GaOOH 527 and thick Ga₂O₃ 528 result in the electrical conductivity of the oxidized liquid metal 525 being significantly decreased. Additionally, the oxidation may convert the oxidized liquid metal 525 from a liquid to a solid. A low electrical conductivity, solid, material is not suitable for use with socket pin architectures, such as those described herein.

Referring now to FIG. 5B an image of a liquid metal 520 is shown, in accordance with an embodiment. The image shown in FIG. 5B may be a SEM image that is used to inspect a surface of the liquid metal 520. In an embodiment, the surface may comprise pure liquid metal regions 521. The liquid metal regions 521 may look substantially smooth. For example, portions of the surface may comprise metal without the inclusion of oxygen. In the case of a gallium based liquid metal, the pure liquid metal regions 521 may comprise gallium, tin, zinc, indium, or other metallic elements. In an embodiment, the liquid metal 520 may further include oxide regions 528. The oxide regions 528 may look like a rippled surface. However, in contrast to the oxide regions 528 in FIG. 5A, the oxide regions 528 in FIG. 5B are thinner. For example, the oxide regions 528 may have a thickness that is approximately 1 μm or less. The small thickness of the oxide regions 528 coupled with the pure liquid metal regions 521 allow for the liquid metal 520 to maintain excellent electrical conductivity. Further, the liquid metal 520 maintains a liquid phase. As such, the liquid metal 520 is a good candidate for socket pin architectures, such as those described herein.

Referring now to FIG. 5C, a cross-sectional illustration of an oxidized liquid metal 525 is shown, in accordance with an embodiment. In an embodiment, the oxidized liquid metal 525 may comprise a solid, porous, structure. For example, pores 517 may be provided throughout the oxidized liquid metal 525. In an embodiment, cracks 522 and the like may also be provided into the oxidized liquid metal 525. In an embodiment, a thick oxide 528 (e.g., Ga₂O₃) may be provided around a perimeter of the oxidized liquid metal 525. For example, the oxide 528 may have a thickness that is approximately 1 μm or more. In an embodiment, the surface of the oxidized liquid metal 525 may also comprise a metal oxide monohydroxide crystal structure 527, such as GaOOH. While the metal oxide monohydroxide crystal structure 527 is provided around a complete perimeter of the oxidized liquid metal 525 in FIG. 5C, it is to be appreciated that the oxide 528 may also be provide at an outermost surface of the oxidized liquid metal 525 in some embodiments. As described above the oxidization of the liquid metal may result in the conversion of the material into a solid with poor electrical conductivity. As such, the oxidized liquid metal 525 is not suitable for use in socket pin architectures.

Referring now to FIG. 5D, a cross-sectional illustration of a liquid metal 520 is shown, in accordance with an embodiment. In an embodiment, the liquid metal 520 may not have been exposed to high temperatures and/or high humidity environments. In some embodiments, the liquid metal 520 shown in FIG. 5D may be protected by an antioxidant layer, as will be described in greater detail below. The liquid metal 520 may comprise a thin oxide layer 528. For example, the oxide layer 528 may comprise Ga₂O₃ or the like. The oxide layer 528 may have a thickness that is approximately 1 μm or less. As such, the electrical conductivity is not significantly impacted. Additionally, while shown as a uniform coating over the liquid metal 520, it is to be appreciated that the oxide layer 528 may be non-continuous over the entire surface of the liquid metal 520. For example, portions of pure liquid metal 520 may be provided along the outer surface in some embodiments. Since the liquid metal 520 avoids the formation of metal oxide monohydroxide crystal structures, the liquid metal 520 maintains a liquid phase with good electrical conductivity. As such, the liquid metal 520 is a good candidate for use in a socket pin architecture.

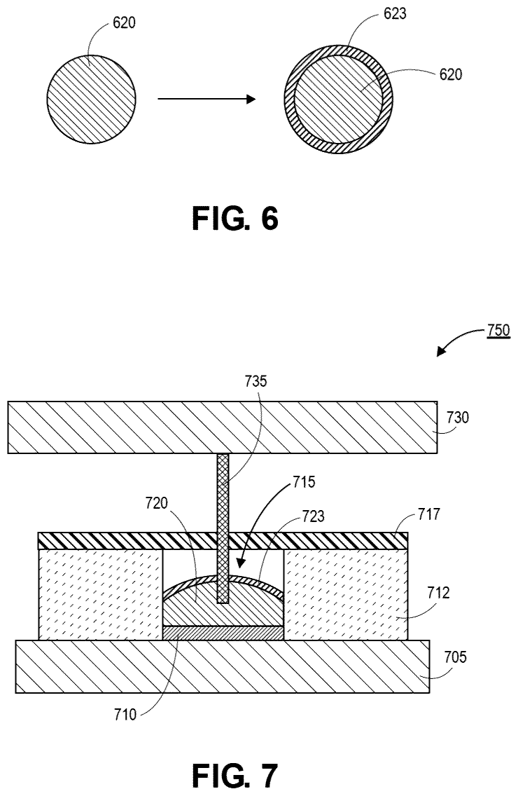

Referring now to FIG. 6, a cross-sectional illustration depicting a process for protecting a liquid metal 620 is shown, in accordance with an embodiment. In an embodiment, the liquid metal 620 is coated with a protective layer 623. In a particular embodiment, the protective layer 623 may be an antioxidant. The antioxidant protective layer 623 may be any suitable material that minimizes or prevents oxidation of the underlying liquid metal 620. For example, the antioxidant may comprise one or more of a sodium ascorbate, a thiol, selenium, a carotenoid (e.g., beta-carotene or zeaxanthin), an oil, a silicone oil, a lubricant, a grease, an acrylic coating, a propyl acetate, an acetone, an ethanol, a thermal curable resin, an UV curable resin, a glycerin, an amine antioxidant, a phenolic antioxidant, a phenol-phosphite antioxidant, a phosphite antioxidant, a dithiocarbamate antioxidant, a thioester antioxidant, and a tolumidazole antioxidant.

The protective layer 623 may be a fluid that surrounds the liquid metal 620. The protective layer 623 may block water and oxygen from reaching the underlying liquid metal 620. A thickness of the protective layer 623 may be approximately 1 μm or more, approximately 5 μm or more, or approximately 10 μm or more. Though, it is to be appreciated that thinner protective layers 623 may also be used in some embodiments. The protective layer 623 may be dispensed over the liquid metal 620 with any suitable dispensing processes. For example, a nozzle based dispensing process is described in greater detail below.

Referring now to FIG. 7, a cross-sectional illustration of a system 750 is shown, in accordance with an embodiment. In an embodiment, the system 750 may include a board 705, such as a PCB. In an embodiment, a pad 710 on the board 705 is electrically coupled to a package substrate 730 by a pin 735. The pin 735 may be electrically coupled to the pad 710 through a liquid metal 720. The liquid metal 720 may be confined by a confinement layer 712 that defines a cavity 715. The liquid metal 720 may be held within the cavity 715. The confinement layer 712 may include an oxide, a polymer, or any other electrically insulating material. In an embodiment, the liquid metal 720 partially fills the cavity 715. The top of the cavity 715 may be sealed by a capping layer 717. The capping layer 717 may be an electrically insulating material that can seal the cavity 715 to minimize the amount of air or moisture that enter the cavity 715. The capping layer 717 may be pierced by the pin 735.

In an embodiment, the liquid metal 720 may comprise a gallium based liquid metal. The gallium may be alloyed with other elements such as, for example, tin, zinc, indium, and other metallic elements. In an embodiment, the liquid metal 720 may comprise approximately 80 atomic percent gallium or more, approximately 90 atomic percent gallium or more, or approximately 99 atomic percent gallium or more.

In an embodiment, a protective layer 723 is provided over the top surface of the liquid metal 720. The protective layer 723 may include an antioxidant. For example, any of the antioxidant materials described in greater detail above may be used for the protective layer 723. The protective layer 723 may also be a liquid material. A density of the protective layer 723 may be less than a density of the liquid metal 720. As such, the protective layer 723 maintains its position over the top surface of the liquid metal 720. In an embodiment, a volume of the liquid metal 720 is greater than a volume of the protective layer 723. In an embodiment, a thickness of the protective layer 723 may be approximately 1 μm or more. In an embodiment, the protective layer 723 prevents oxygen and water from reaching the underlying liquid metal 720. As such, the liquid metal 720 remains in a liquid phase, even in the presence of high heat and/or high humidity. This improves the reliability of the system 750.

In FIG. 7, a second level interconnect (SLI) architecture with a package substrate 730 coupled to a board 705 is shown, in accordance with an embodiment. However, it is to be appreciated that first level interconnect (FLI) architectures may also employ the use of a liquid metal 720 that is covered by a protective layer 723. For example, a cavity may be provided in the package substrate 730 and filled with the liquid metal 720 and the protective layer 723. In such an embodiment, a pin extending out from a die may be inserted into the cavity in order to electrically couple the package substrate 730 to the die.

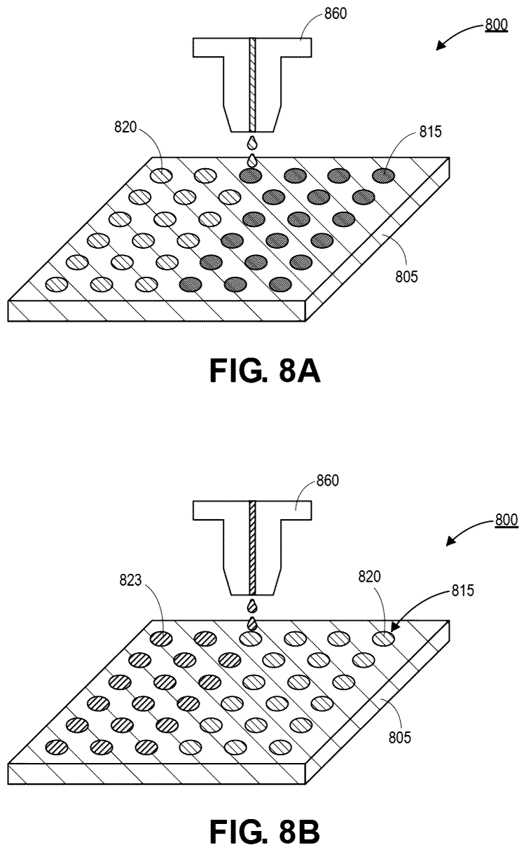

Referring now to FIGS. 8A and 8B, a pair of illustrations depicting a process for dispensing a liquid metal 820 and a protective layer 823 in a system 800 is shown, in accordance with an embodiment. As shown in FIG. 8A, a dispensing tool 860 (e.g., a nozzle) dispenses liquid metal 820 into cavities 815 on a board 805. The illustrated embodiment omits the presence of a confinement layer, but embodiments may include confinement layers in some instances. Otherwise, the cavity 815 may be formed directly into the board 805. The dispensing tool 860 may be moved across the surface of the board 805 in order to dispense the liquid metal 820.

Referring now to FIG. 8B, an illustration of the system 800 during the dispensing of a protective layer 823 is shown, in accordance with an embodiment. In an embodiment, the protective layer 823 may comprise an antioxidant, such as one of those described in greater detail above. In an embodiment, the protective layer 823 may be dispensed with a dispensing tool 860. The dispensing tool 860 in FIG. 8B may be the same dispensing tool 860 shown in FIG. 8A. Though, two different dispensing tools 860 may be used to dispense the liquid metal 820 and the protective layer 823.

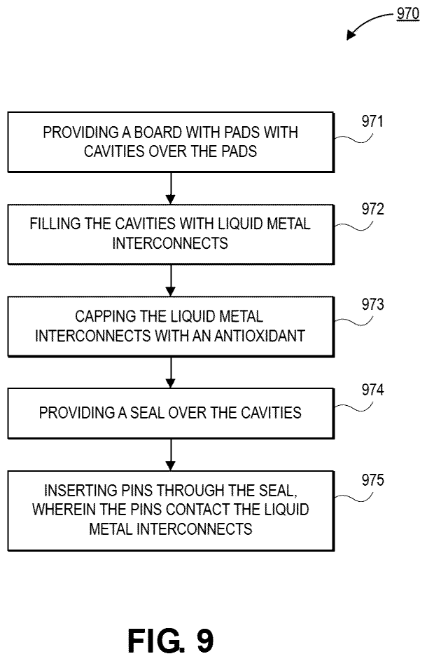

Referring now to FIG. 9, a process flow diagram depicting a process 970 for forming a packaged system is shown, in accordance with an embodiment. In an embodiment, the process 970 may begin with operation 971, which comprises providing a board with pads with cavities over the pads. The cavities may be defined by a confinement layer or by portions of the board. In an embodiment, the process 970 may continue with operation 972, which comprises filling the cavities with liquid metal interconnects. The liquid metal may be dispensed with a nozzle or the like. In an embodiment, the process 970 continues with operation 973, which comprises capping the liquid metal interconnects with an antioxidant. The antioxidant may be any of the antioxidant materials described in greater detail above. The antioxidant may be dispensed with a nozzle or other dispensing tool. The nozzle to dispense the antioxidant may be the same nozzle used to dispense the liquid metal interconnects or a different nozzle. In an embodiment, the process 970 continues with operation 794, which comprises providing a seal over the cavities. The seal may be a capping layer that spans across a top surface of the cavity. The process 970 may continue with operation 975, which comprises inserting pins through the seal, wherein the pins contact the liquid metal interconnects. In an embodiment, the pin passes through a thickness of the antioxidant and directly contacts the liquid metal interconnects. The pins may couple the pads of the board to an overlying package substrate or the like.

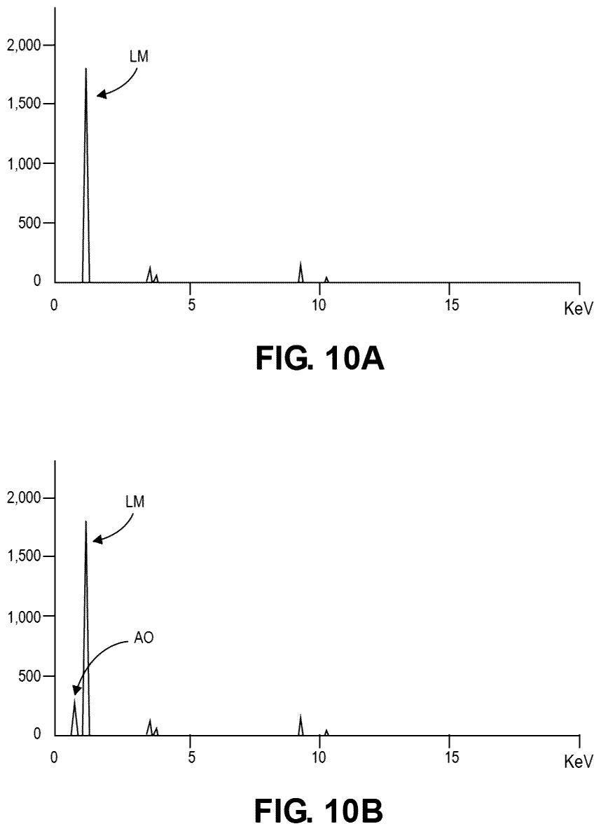

It is to be appreciated that the presence of the protective antioxidant layer can be detected using various material investigation techniques. For example, SEM images similar to those shown in FIGS. 5A and 5B may be used to show the absence of metal oxide monohydroxide crystal structures and a thick metal oxide. Surface analysis (e.g., EDX, XPS, etc.) can also be used to detect the elements present at the surface. For example, FIGS. 10A and 10B show example EDX spectrums. The spectrum shown in FIG. 10A is a spectrum of liquid metal (LM) without an antioxidant layer. As shown, a large peak corresponding to the main constituent of the liquid metal (e.g., gallium) is provided. Additional smaller peaks may indicate alloying elements. In FIG. 10B, the EDX spectrum shows a liquid metal with an antioxidant (AO). The AO has a distinct peak that can be detected. The location and height of the AO peak may correspond with the particular material (or materials) of the antioxidant. That is, the EDX spectrum in FIG. 10B is used as an example, and other spectrums with different peaks may also be indicative of the presence of an antioxidant.

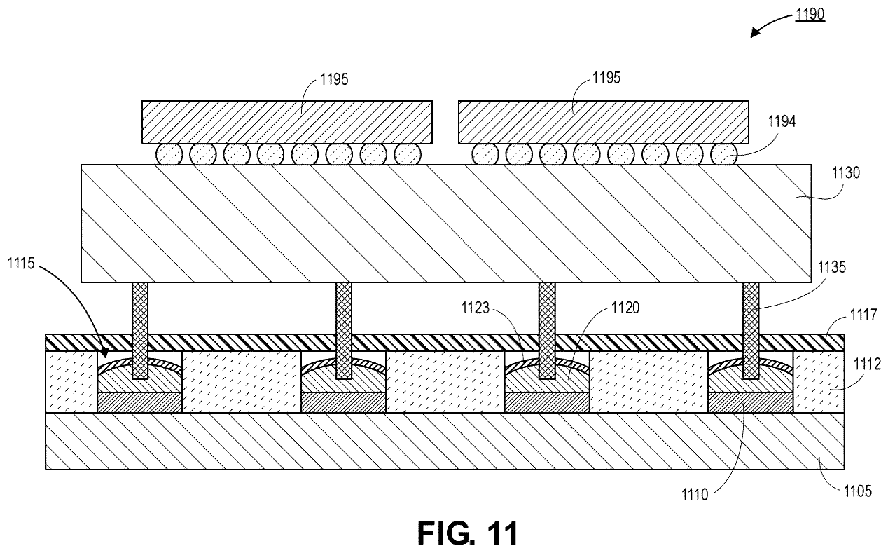

Referring now to FIG. 11, a cross-sectional illustration of an electronic system 1190 is shown, in accordance with an embodiment. In an embodiment, a board 1105, such as a PCB may be coupled to a package substrate 1130 with a socket architecture. In an embodiment, a confinement layer 112 over the board 1105 may include cavities 1115 over the pads 1110. In an embodiment, a liquid metal 1120 and a protective layer 1123 may be provided in the cavities 1115. A pin 1135 may pass through a capping layer 1117 and contact the liquid metal 1120.

In an embodiment, one or more dies 1195 may be coupled to the package substrate 1130 by interconnects 1194. The interconnects 1194 may include solder, copper bumps, or any other FLI architecture. In an embodiment, the dies 1195 may include any type of die, such as a central processing unit (CPU), a graphics processing unit (GPU), an XPU, a system on a chip (SoC), a communications die, or a memory.

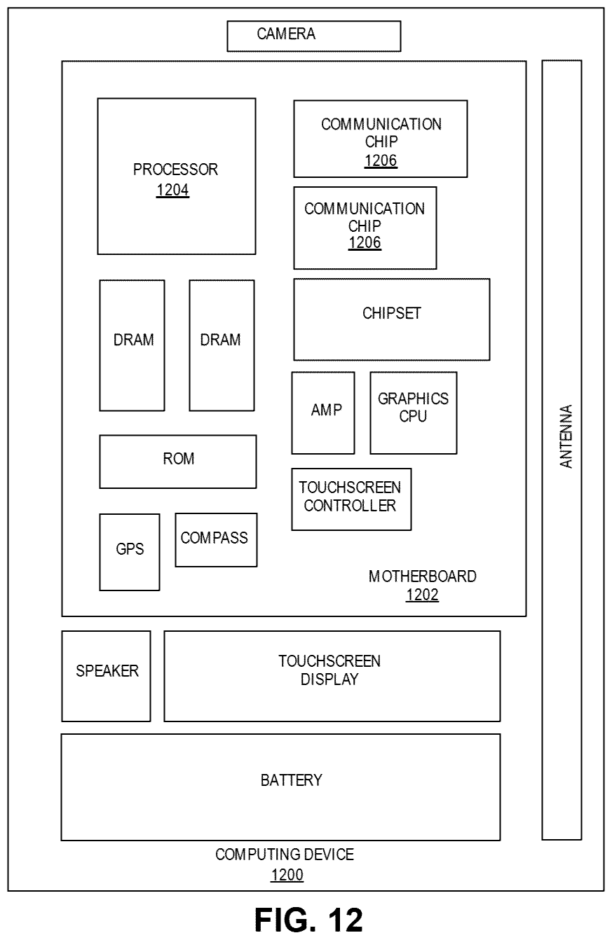

FIG. 12 illustrates a computing device 1200 in accordance with one implementation of the invention. The computing device 1200 houses a board 1202. The board 1202 may include a number of components, including but not limited to a processor 1204 and at least one communication chip 1206. The processor 1204 is physically and electrically coupled to the board 1202. In some implementations the at least one communication chip 1206 is also physically and electrically coupled to the board 1202. In further implementations, the communication chip 1206 is part of the processor 1204.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 1206 enables wireless communications for the transfer of data to and from the computing device 1200. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1206 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1200 may include a plurality of communication chips 1206. For instance, a first communication chip 1206 may be dedicated to shorter range wireless communications such as Wi-Fi and Bluetooth and a second communication chip 1206 may be dedicated to longer range wireless communications such as GPS, EDGE, GPRS, CDMA, WiMAX, LTE, Ev-DO, and others.

The processor 1204 of the computing device 1200 includes an integrated circuit die packaged within the processor 1204. In some implementations of the invention, the integrated circuit die of the processor may be part of an electronic package with a socket SLI architecture that includes a liquid metal protected by an antioxidant, in accordance with embodiments described herein. The term “processor” may refer to any device or portion of a device that processes electronic data from registers and/or memory to transform that electronic data into other electronic data that may be stored in registers and/or memory.

The communication chip 1206 also includes an integrated circuit die packaged within the communication chip 1206. In accordance with another implementation of the invention, the integrated circuit die of the communication chip may be part of an electronic package with a socket SLI architecture that includes a liquid metal protected by an antioxidant, in accordance with embodiments described herein.

In an embodiment, the computing device 1200 may be part of any apparatus. For example, the computing device may be part of a personal computer, a server, a mobile device, a tablet, an automobile, or the like. That is, the computing device 1200 is not limited to being used for any particular type of system, and the computing device 1200 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a board, comprising: a substrate; a pad over the substrate; a confinement layer over the substrate, wherein the confinement layer defines a cavity over the pad; a liquid metal on the pad; and a protective layer over the liquid metal.

Example 2: the board of Example 1, wherein the liquid metal comprises gallium.

Example 3: the board of Example 1 or Example 2, wherein the protective layer is an antioxidant.

Example 4: the board of Example 3, wherein the antioxidant comprises one or more of a sodium ascorbate, a thiol, selenium, a carotenoid, an oil, a silicone oil, a lubricant, a grease, an acrylic coating, a propyl acetate, an acetone, an ethanol, a thermal curable resin, an UV curable resin, and a glycerin.

Example 5: the board of Example 4, wherein the carotenoid comprises beta-carotene or zeaxanthin.

Example 6: the board of Examples 3-5, wherein the antioxidant comprises one or more of an amine antioxidant, a phenolic antioxidant, a phenol-phosphite antioxidant, a phosphite antioxidant, a dithiocarbamate antioxidant, a thioester antioxidant, and a tolumidazole antioxidant.

Example 7: the board of Examples 1-6, further comprising: a capping layer over the cavity.

Example 8: the board of Examples 1-7, wherein a volume of the liquid metal is greater than a volume of the protective layer.

Example 9: the board of Examples 1-8, wherein the protective layer is a fluid at temperatures where the liquid metal is a fluid.

Example 10: the board of Examples 1-9, wherein the liquid metal has an oxide coating without the formation of metal oxide monohydroxide crystals.

Example 11: an electronic package, comprising: a package substrate; a board coupled to the package substrate with socket interconnects, wherein a board side of the socket interconnects includes a liquid metal with an antioxidant coating.

Example 12: the electronic package of Example 11, wherein the liquid metal comprises gallium.

Example 13: the electronic package of Example 12, wherein a surface of the liquid metal comprises gallium and gallium oxide.

Example 14: the electronic package of Example 13, wherein the surface of the liquid metal does not include gallium oxide monohydroxide crystals.

Example 15: the electronic package of Examples 11-14, wherein the liquid metal contacts a pad on the board.

Example 16: the electronic package of Example 15, wherein the liquid metal is confined by a confinement layer, and wherein a capping layer is over the liquid metal.

Example 17: the electronic package of Examples 11-16, wherein the antioxidant comprises one or more of a sodium ascorbate, a thiol, selenium, a carotenoid, an oil, a silicone oil, a lubricant, a grease, an acrylic coating, a propyl acetate, an acetone, an ethanol, a thermal curable resin, an UV curable resin, a glycerin, an amine antioxidant, a phenolic antioxidant, a phenol-phosphite antioxidant, a phosphite antioxidant, a dithiocarbamate antioxidant, a thioester antioxidant, and a tolumidazole antioxidant.

Example 18: an electronic system, comprising: a board; a package substrate coupled to the board through a socket, wherein a board side of the socket comprises a liquid metal and an antioxidant over the liquid metal; and a die coupled to the package substrate.

Example 19: the electronic system of Example 18, wherein the antioxidant comprises one or more of a sodium ascorbate, a thiol, selenium, a carotenoid, an oil, a silicone oil, a lubricant, a grease, an acrylic coating, a propyl acetate, an acetone, an ethanol, a thermal curable resin, an UV curable resin, a glycerin, an amine antioxidant, a phenolic antioxidant, a phenol-phosphite antioxidant, a phosphite antioxidant, a dithiocarbamate antioxidant, a thioester antioxidant, and a tolumidazole antioxidant.

Example 20: the electronic system of Example 18 or Example 19, wherein the electronic system is part of a personal computer, a server, a mobile device, a tablet, or an automobile.

What is claimed is:

1. A board, comprising:
a substrate;
a pad over the substrate;
a confinement layer over the substrate, wherein the confinement layer defines a cavity over the pad;
a liquid metal on the pad; and
a protective layer over the liquid metal.

2. The board of claim 1, wherein the liquid metal comprises gallium.

3. The board of claim 1, wherein the protective layer is an antioxidant.

4. The board of claim 3, wherein the antioxidant comprises one or more of a sodium ascorbate, a thiol, selenium, a carotenoid, an oil, a silicone oil, a lubricant, a grease, an acrylic coating, a propyl acetate, an acetone, an ethanol, a thermal curable resin, an UV curable resin, and a glycerin.

5. The board of claim 4, wherein the carotenoid comprises beta-carotene or zeaxanthin.

6. The board of claim 3, wherein the antioxidant comprises one or more of an amine antioxidant, a phenolic antioxidant, a phenol-phosphite antioxidant, a phosphite antioxidant, a dithiocarbamate antioxidant, a thioester antioxidant, and a tolumidazole antioxidant.

7. The board of claim 1, further comprising:
a capping layer over the cavity.

8. The board of claim 1, wherein a volume of the liquid metal is greater than a volume of the protective layer.

9. The board of claim 1, wherein the protective layer is a fluid at temperatures where the liquid metal is a fluid.

10. The board of claim 1, wherein the liquid metal has an oxide coating without the formation of metal oxide monohydroxide crystals.

11. An electronic package, comprising:
a package substrate;
a board coupled to the package substrate with socket interconnects, wherein a board side of the socket interconnects includes a liquid metal with an antioxidant coating.

12. The electronic package of claim 11, wherein the liquid metal comprises gallium.

13. The electronic package of claim 12, wherein a surface of the liquid metal comprises gallium and gallium oxide.

14. The electronic package of claim 13, wherein the surface of the liquid metal does not include gallium oxide monohydroxide crystals.

15. The electronic package of claim 11, wherein the liquid metal contacts a pad on the board.

16. The electronic package of claim 15, wherein the liquid metal is confined by a confinement layer, and wherein a capping layer is over the liquid metal.

17. The electronic package of claim 11, wherein the antioxidant comprises one or more of a sodium ascorbate, a thiol, selenium, a carotenoid, an oil, a silicone oil, a lubricant, a grease, an acrylic coating, a propyl acetate, an acetone, an ethanol, a thermal curable resin, an UV curable resin, a glycerin, an amine antioxidant, a phenolic antioxidant, a phenol-phosphite antioxidant, a phosphite antioxidant, a dithiocarbamate antioxidant, a thioester antioxidant, and a tolumidazole antioxidant.

18. An electronic system, comprising:
a board;
a package substrate coupled to the board through a socket, wherein a board side of the socket comprises a liquid metal and an antioxidant over the liquid metal; and
a die coupled to the package substrate.

19. The electronic system of claim 18, wherein the antioxidant comprises one or more of a sodium ascorbate, a thiol, selenium, a carotenoid, an oil, a silicone oil, a lubricant, a grease, an acrylic coating, a propyl acetate, an acetone, an ethanol, a thermal curable resin, an UV curable resin, a glycerin, an amine antioxidant, a phenolic antioxidant, a phenol-phosphite antioxidant, a phosphite antioxidant, a dithiocarbamate antioxidant, a thioester antioxidant, and a tolumidazole antioxidant.

20. The electronic system of claim 18, wherein the electronic system is part of a personal computer, a server, a mobile device, a tablet, or an automobile.
